(19) United States
(12) Patent Application Publication
(10) Pub. No.: US 2011/0255251 A1
(43) Pub. Date: Oct. 20, 2011

(54) ELECTRONIC PACKAGE AND DISPLAY APPARATUS

(75) Inventor: Kohei Kitagawa, Osaka-shi (JP)

(73) Assignee: SHARP KABUSHIKI KAISHA, Osaka-shi, Osaka (JP)

(21) Appl. No.: 13/141,700

(22) PCT Filed: Jan. 18, 2010
(86) PCT No.: PCT/JP2010/050479

§ 371 Date: Jun. 23, 2011

(30) Foreign Application Priority Data
Jan. 30, 2009 (JP) 2009-019600

(51) Int. Cl. H05K 1/11

(52) U.S. Cl. 361/751; 361/796

(57) ABSTRACT

Two bezels (BZ1, BZ2) which constitute a housing unit (UT) comprise a FPC board (PB1) for a panel and an FPC board (PB2) for an LED. The FPC hoard (PB1) for a panel and the FPC board (PB2) for an LED are connected to each other through a solder (11). An exposure opening (HL) through which the solder (11) is exposed from the inside of the housing unit (UT) to the outside thereof is formed in the portion (e.g., the rear bezel (BZ2)) of the housing unit (UT) that is located in front of the solder (11).

### TECHNICAL FIELD

The present invention relates to an electronic package and a display apparatus (for example, a liquid crystal display apparatus) including the electronic package.

### BACKGROUND ART

Recent years have seen a market demand for thin or compact electronic equipment. Examples of such electronic equipment include a thin liquid crystal television. A liquid crystal display apparatus included in the liquid crystal television often uses, for the purpose of thickness reduction, an FPC (flexible printed circuit) board that is a circuit board having flexibility (see Patent Document 1).

Furthermore, the FPC board included in the liquid crystal display apparatus is not limited to one in number, and a plurality of FPC boards may be included therein. For example, a liquid crystal display apparatus 269 shown in FIGS. 20A and 20B includes a panel FPC board (first circuit board) pb11 connected to a liquid crystal display panel 249 and an LED FPC board (second circuit board) pb22 on which an LED (light emitting diode) as a light source is mounted.

In the above-described case where the plurality of FPC boards pb11•pb22 are included, conduction needs to be established between the FPC boards ph11•pb22. To this end, solder 211 is used that is an electrically conductive adhesive. For example, as shown in FIG. 21 that is a partially enlarged view of FIG. 20B, a connection portion c11 (see a hatched area) in the panel FPC board pb11 and a connection portion c22 (see a halftone dotted area) on the LED FPC board pb22 are electrically connected to each other by use of the solder 211.

If, however, bezels (front bezel bz11•rear bezel bz22) that constitute a housing of the liquid crystal display apparatus 269 are made of a metal having conductivity, there arises a problem that a short circuit might occur between the bezels bz11•bz22 and the solder 211 (herein, these bezels bz11•bz22 are referred to collectively as a housing unit ut, and the bezels bz11•bz22 with the FPC circuit boards pb11•pb22 housed therebetween are referred to as an electronic package pg).

As a solution to this problem, in the liquid crystal display apparatus 269 shown in FIGS. 20A and 20B, a part of the panel FPC board pb11 and a part of the LED FPC board pb22 are drawn out from the inside surrounded by the bezels bz11•bz22 to the outside. Moreover, the connection portions c11•c22 are formed on the drawn-out parts of these FPC boards pb11•pb22, and the solder 211 is applied so as to cover both the connection portions c11•c22 (see FIGS. 20B and 21). This prevents the solder 211 from coming into contact with, for example, the inner surface of the rear bezel bz, thereby preventing the occurrence of a short circuit (leakage).

### LIST OF CITATIONS

### Patent Literature

Patent Document 1: JP-A-2006-154292

### SUMMARY OF THE INVENTION

### 1. Technical Problems

It can be said, however, that, positioned on the outside of the liquid crystal display apparatus 269, the respective parts of the FPC boards pb11•pb22, to which the solder 211 is applied, are relatively unstable free ends. This raises the possibility that leakage might occur between the solder 211 and the outer surfaces of the bezels bz11•bz22 due to displacements of the FPC boards pb11•pb22. Furthermore, if a liquid crystal television that includes the liquid crystal display apparatus 269 includes a metallic component, in the liquid crystal television, leakage might occur between the metallic component and the solder 111.

As a possible method of preventing the occurrence of such leakage, the solder 211 is covered with an insulation member. This, however, increases the cost of the liquid crystal display apparatus 269 (and accordingly, of the liquid crystal television) due to the insulation member being further included. In addition, this requires that consideration be given to the thickness of the insulation member and thus might further lead to an increase in the thicknesses of the liquid crystal display apparatus 269 and the liquid crystal television.

The present invention has been made to solve the above-described problems. It is an object of the present invention to provide a thin electronic package and the like in which leakage attributable to an electrically conductive adhesive is prevented from occurring without the use of an additional separate member.

### Solution to the Problems

An electronic package includes: a first circuit board; a second circuit board; and a housing unit that houses both the circuit boards, and conduction is established between the first circuit board and the second circuit board via an electrically conductive adhesive. Furthermore, in the electronic package, an exposure hole through which the electrically conductive adhesive is exposed from an inside of the housing unit to an outside thereof is formed at a part of the housing unit, which is positioned in front of the electrically conductive adhesive.

According to this configuration, even if the housing unit is made of a metal having electrical conductivity, in front of the electrically conductive adhesive, the exposure hole is positioned and no metal is present. Thus, in the electronic package, the occurrence of leakage attributable to the electrically conductive adhesive is prevented. Furthermore, the occurrence of leakage is prevented without requiring that an insulation member for covering the electrically conductive adhesive be provided in the electronic package. Thus, no extra cost involved in further including an insulation member is incurred, and, moreover, there occurs no increase in the thickness of the electronic package due to the thickness of the insulation member.

Electronic equipment including the electronic package is represented by a display apparatus. Examples thereof include a display apparatus in which the first circuit board is a flexible circuit board connected to a display panel, the second circuit board is a flexible circuit board on which a light emitting element is mounted, and the electrically conductive adhesive is solder.

Furthermore, preferably, in the display apparatus configured as above, a chassis that has a shape of a frame and forms a skeleton of the display apparatus is housed in the housing unit, and a part of the second circuit board, to which the electrically conductive adhesive is applied, is bent so as to be housed within the frame of the chassis.

According to this configuration, there is no need for a drawing-out opening for drawing out the second circuit board to the outside of the frame of the chassis, and thus the chassis is increased in strength. This also leads to an increase in the strength of the display apparatus.

Furthermore, preferably, the housing unit is composed of a plurality of housings, and a drawing-out opening through which at least one of the first circuit board and the second circuit board is drawn out to the outside of the housing unit is formed in at least one of the housings, in which case the drawing-out opening is a loop-shaped opening.

According to this configuration, since the opening is loop-shaped, a part of the at least one of the housings at a periphery of the opening functions as a beam, thereby preventing the strength of the at least one of the housings from being excessively deteriorated. This also prevents the strength of the display apparatus including the at least one of the housings from being excessively deteriorated.

### Advantageous Effects of the Invention

According to the electronic package of the present invention, leakage attributable to an electrically conductive adhesive member is prevented from occurring without the use of a separate insulation member. Thus, this electronic package requires no extra cost involved in further including a separate insulation member and, moreover, eliminates the need for the thickness of the insulation member to be taken into consideration, thereby achieving thickness reduction.

### BRIEF DESCRIPTION OF DRAWINGS

FIG. 1 is a partially enlarged view of FIG. 2.

FIG. 2 is a perspective view of a liquid crystal display apparatus.

FIG. 3 is a perspective view of the liquid crystal display apparatus.

FIG. 4 is an exploded perspective view of the liquid crystal display apparatus.

FIG. 5 is a perspective view of the liquid crystal display apparatus, in which bezels are omitted.

FIG. 6 illustrates one process step in a process for fabricating the liquid crystal display apparatus, and is a perspective view showing an LED module being brought close to a light guide plate, etc.

FIG. 7 illustrates one process step in the process for fabricating the liquid crystal display apparatus, and is a perspective view showing an LED FPC board being about to be bent, etc.

FIG. 8 illustrates one process step in the process for fabricating the liquid crystal display apparatus, and is a perspective view showing the LED FPC board that has been bent, etc.

FIG. 9 illustrates one process step in the process for fabricating the liquid crystal display apparatus, and is a perspective view showing an optical sheet group stacked on the light guide plate, etc.

FIG. 10 illustrates one process step in the process for fabricating the liquid crystal display apparatus, and is a perspective view showing a liquid crystal display panel being stacked on the light guide plate, etc.

FIG. 11 illustrates one process step in the process for fabricating the liquid crystal display apparatus, and is a perspective view showing a panel FPC board being about to be bent, etc.

FIG. 12 illustrates one process step in the process for fabricating the liquid crystal display apparatus, and is a perspective view showing the panel FPC board that has been bent, etc.

FIG. 13 is a perspective view showing a part of the liquid crystal display apparatus as seen from a non-reflection surface side of a reflection sheet.

FIG. 14 is a partially enlarged view of FIG. 13.

FIG. 15 illustrates one process step in the process for fabricating the liquid crystal display apparatus, and is a perspective view showing a rear bezel being placed over the reflection sheet, etc.

FIG. 16 is an exploded perspective view of the liquid crystal display apparatus.

FIG. 17A shows a component included in the liquid crystal display apparatus shown in FIG. 16, and is a side view of a front bezel.

FIG. 17B shows a component included in the liquid crystal display apparatus shown in FIG. 16, and is a side view of a built-in chassis.

FIG. 17C shows a component included in the liquid crystal display apparatus shown in FIG. 16, and is a side view of the rear bezel.

FIG. 18 is an exploded perspective view of a liquid crystal display apparatus as a comparative example.

FIG. 19A shows a component included in the liquid crystal display apparatus shown in FIG. 18, and is a side view of a front bezel.

FIG. 19B shows a component included in the liquid crystal display apparatus shown in FIG. 18, and is a side view of a built-in chassis.

FIG. 19C shows a component included in the liquid crystal display apparatus shown in FIG. 18, and is a side view of a rear bezel.

FIG. 20A is a perspective view of a conventional liquid crystal display apparatus.

FIG. 20B is a perspective view of the conventional liquid crystal display apparatus.

FIG. 21 is a partially enlarged view of FIG. 20B.

### DESCRIPTION OF EMBODIMENTS

### Embodiment 1

Hereinafter, one embodiment will be described referring to the appended drawings. In some of the drawings, hatching, reference signs of members, and the like may be omitted for the sake of convenience, in which case reference should be made to other drawings. Hatching may be provided, however, even in a view other than a cross-sectional view for the sake of convenience.

The following description uses a liquid crystal display apparatus as an example of a display apparatus. There is, however, no limitation thereto. For example, as the display apparatus, an organic EL (electroluminescence) display and a plasma display may also be used. Furthermore, a configuration in which a flexible circuit board is mounted to bezels that constitute the exterior of the liquid crystal display apparatus is referred to as an electronic package (the electronic package can be included not only in a liquid crystal display apparatus but also in various other types of apparatuses).

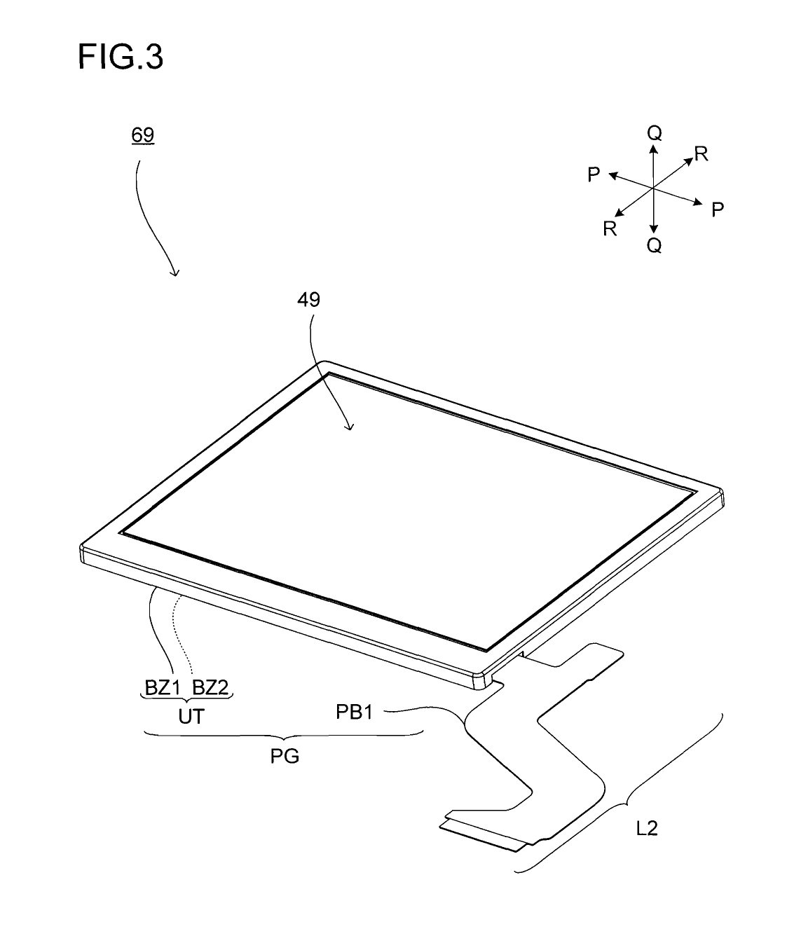

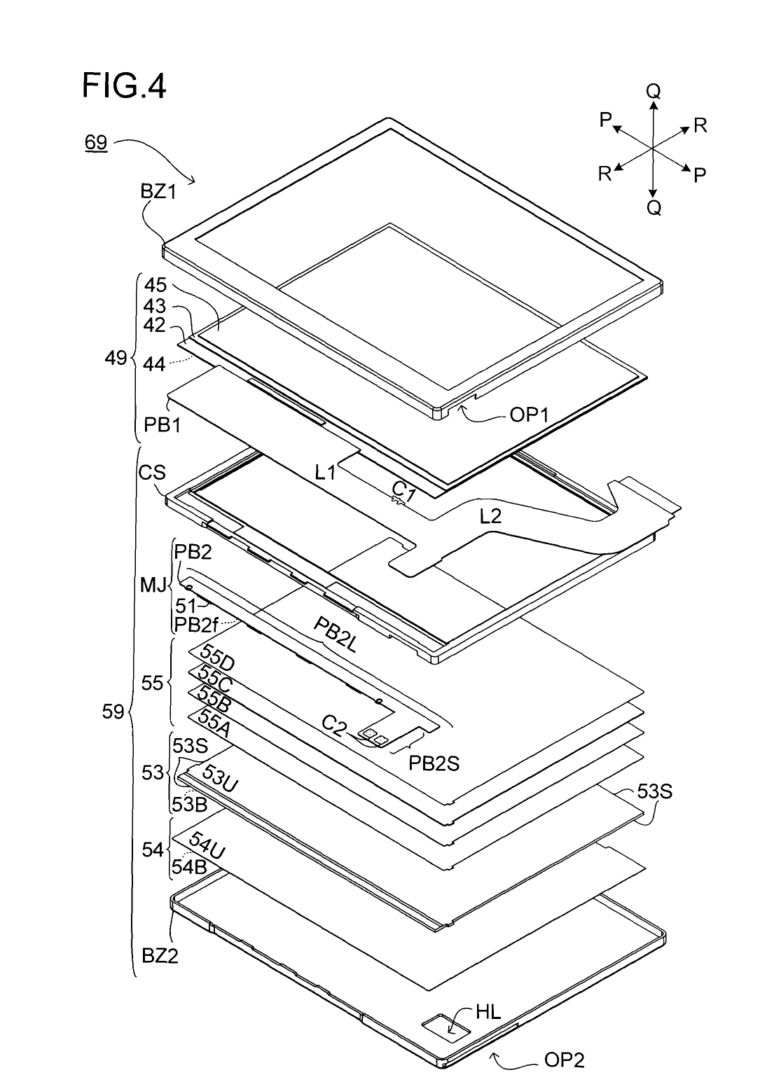

The perspective view in FIG. 3 shows a liquid crystal display apparatus 69 to be included in a liquid crystal television (electronic equipment), and FIG. 4 is an exploded perspective view in which the liquid crystal display apparatus 69 is shown in disassembled form.

As shown in FIG. 4, the liquid crystal display apparatus 69 includes a liquid crystal display panel 49, a backlight unit 59, and bezels BZ (front bezel BZ1•rear bezel BZ2) that hold the liquid crystal display panel 49 and the backlight unit 59 by sandwiching them therebetween.

The shape of the bezels BZ is not particularly limited. For example, as shown in FIG. 4, the rear bezel BZ2 may have a box shape for housing the liquid crystal display panel 49 and the backlight unit 59, and the front bezel BZ1 may have a frame shape that fits over the rear bezel BZ2 (it can be said that these bezels BZ1•BZ2 constitute a housing since they house members, and these bezels BZ1•BZ2 as a unit can be referred to as a housing unit UT).

The liquid crystal display panel 49 includes an active matrix substrate 42, an opposed substrate 43, polarization films 44•45, and a panel FPC (flexible printed circuit) board PB1.

To be more specific, the liquid crystal display panel 49 is formed as follows. That is, the active matrix substrate 42 including a switching element such as a TFT (thin film transistor) and the opposed substrate 43 to be disposed so as to be opposed to the active matrix substrate 42 are laminated to each other by use of a sealing material (not shown). Then, liquid crystal (not shown) is injected into a gap between these substrates 42•43. The polarization film 44 is attached on an active matrix substrate 42 side, while the polarization film 45 is attached on an opposed substrate 43 side so that these polarization films 44•45 sandwich the active matrix substrate 42 and the opposed substrate 43 therebetween.

The panel FPC board (first circuit board) PB1 is a flexible board including supply wiring (not shown) through which an electric current is passed. The panel FPC board PB1 is electrically and physically connected to the active matrix substrate 42.

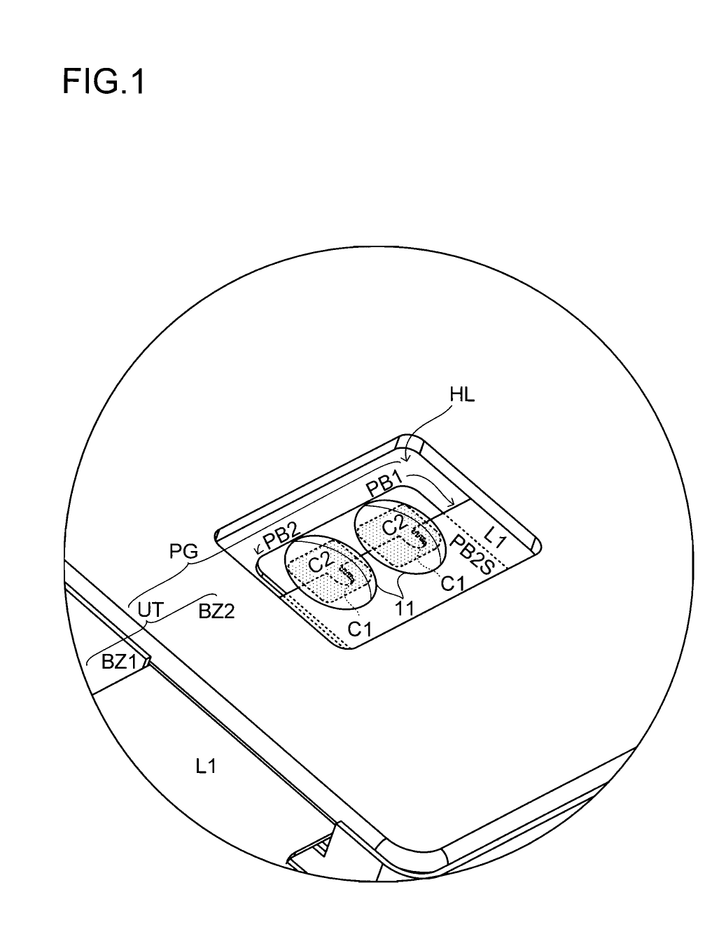

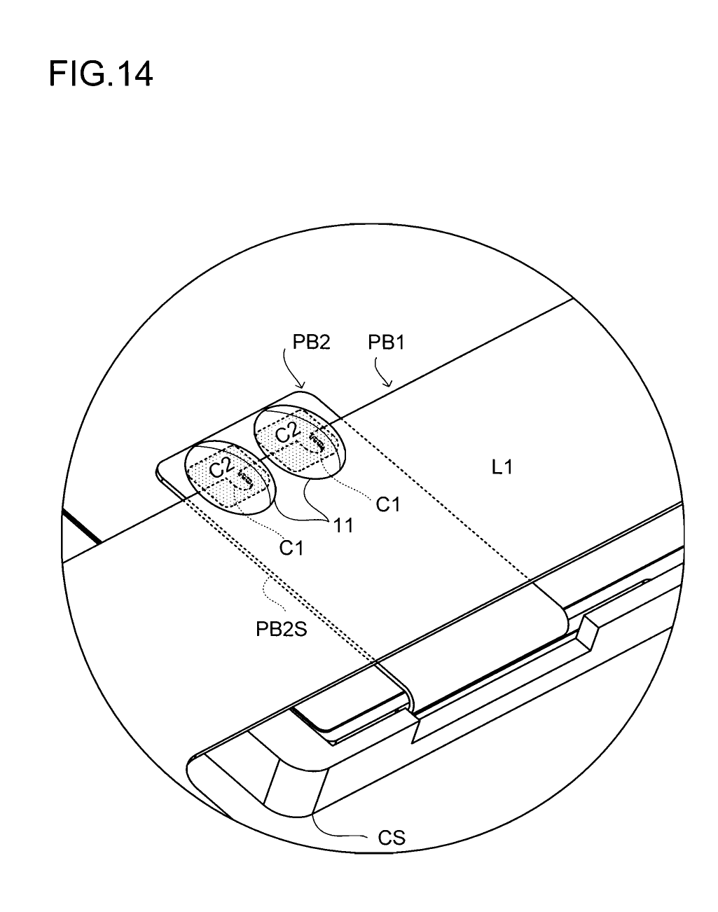

As shown in FIG. 4, the panel FPC board PB1 includes a first extending portion L1 extending along an edge of the active matrix substrate 42 while being connected thereto and a second extending portion L2 connected to the first extending portion L1 while intersecting therewith, which are arranged in series. In the first extending portion L1, a first connection portion C1 is formed that is required for establishing an electrical connection with an LED FPC board PB2, which will be described later (see after-mentioned FIG. 1•FIG. 14).

The backlight unit 59 supplies light to the liquid crystal display panel 49 of a non-light emitting type. The liquid crystal display panel 49 receives light (backlight light) from the backlight unit 59 and thereby fulfills a display function. Thus, allowing the entire surface of the liquid crystal display panel 49 to be irradiated uniformly with light from the backlight unit 59 improves display quality of the liquid crystal display panel 49.

As shown in FIG. 4, the backlight unit 59 configured as above includes an LED module MJ, a light guide plate 53, a reflection sheet 54, an optical sheet group 55 (a diffusion sheet 55A, lens sheets 55B•55C, a diffusion sheet 55D), and a built-in chassis CS.

The LED module MJ is a module that emits light and includes an LED (light emitting diode) 51 that emits light and the LED FPC board (second circuit board) PB2 on which the LED 51 is mounted.

The LED 51 is mounted on an electrode (not shown) formed on a mounting surface PB2f of the LED FPC board PB2 so as to be supplied with an electric current and thereby emits light. Furthermore, in order to secure a light emission amount, preferably, a plurality of the LEDs (light emitting elements, point light sources) 51 are mounted on the LED FPC board PB2 (in the drawings, only some of the LEDs 51 are shown for the sake of convenience).

The LED FPC board PB2 has substantially an L-shape and includes a longer portion PB2L and a shorter portion PB2S. The longer portion PB2L has a length corresponding to longer ones of side surfaces 53S of the light guide plate 53, and the LEDs 51 are arranged on a region of the mounting surface PB2f, which is located in the longer portion PB2L (hereinafter, a direction in which the LEDs 51 are arranged is referred to as an arrangement direction P). Furthermore, in the shorter portion PB2S, a second connection portion C2 is formed that is required for establishing an electrical connection with the panel FPC board PB1 (see after-mentioned FIG. 1•FIG. 14).

The light guide plate 53 is a plate-shaped member having the side surfaces 53S and a top surface 53U and a bottom surface 53B that are positioned so as to sandwich the side surfaces 53S therebetween. One (light receiving surface) of the side surfaces 53S faces a light emitting surface of the LED 51 so as to receive light from the LED 51. The received light is multiply-reflected inside the light guide plate 53 and outputted as planar light from the top surface 53U toward the outside.

The reflection sheet 54 is positioned so as to be covered by the light guide plate 53. One surface of the reflection sheet 54, which faces the bottom surface 53B of the light guide plate 53, functions as a reflection surface 54U (the other surface on the rear side of the reflection surface 54U is defined to be a non-reflection surface 54B). The reflection surface 54U therefore reflects light from the LED 51 and light propagating through the light guide plate 53 back into the light guide plate 53 (more specifically, into the light guide plate 53 through the bottom surface 53B of the light guide plate 53) without allowing leakage thereof.

The optical sheet group 55 includes the two diffusion sheets 55A•55D and the two lens sheets 55B•55C. To be more specific, it can be said that a plurality of sheets laminated in the order of the diffusion sheet 55A, the lens sheet 55B, the lens sheet 55C, and the diffusion sheet 55D constitute the optical sheet group 55.

The diffusion sheet 55A is positioned so as to cover the top surface 53U of the light guide plate 53 and diffuses planar light from the light guide plate 53 so that the light is distributed over the entire area of the liquid crystal display panel 49.

The lens sheets 55B•55C are each an optical sheet that has, for example, a prism shape in the plane thereof and deflects radiation characteristics of light, and are positioned so as to cover the diffusion sheet 55A (more specifically, the lens sheet 55B covers the diffusion sheet 55A, and the lens sheet 55C overlies the lens sheet 55B). The lens sheets 55B•55C therefore condense light traveling from the diffusion sheet 55A and thus provide improved luminance. Light condensed by the lens sheet 55B and light condensed by the lens sheet 55C are diverged in directions intersecting with each other, respectively

The diffusion sheet 55D is positioned so as to cover the lens sheet 55C and diffuses light that has passed through the diffusion sheet 55A and the lens sheets 55B•55C so that the light is distributed over the entire area of the liquid crystal display panel 49.

The built-in chassis (chassis) CS is a frame-shaped member that holds the foregoing various members and forms a skeleton of the liquid crystal display apparatus 69. To be more specific, the built-in chassis CS holds the reflection sheet 54, the light guide plate 53, and the optical sheet group 55 in a state where they are stacked in this order (a direction in which they are stacked is referred to as a stacking direction Q, and a direction intersecting with (for example, a direction orthogonal to) the arrangement direction P and the stacking direction Q is referred to as an intersecting direction R).

In the backlight unit 59 configured as above, light from the LED 51 is outputted in the form of planar light by the light guide plate 53, and the planar light then passes through the optical sheet group 55 and thus is outputted in the form of backlight light having an increased light emission luminance. This backlight light reaches the liquid crystal display panel 49 to allow the liquid crystal display panel 49 to display an image.

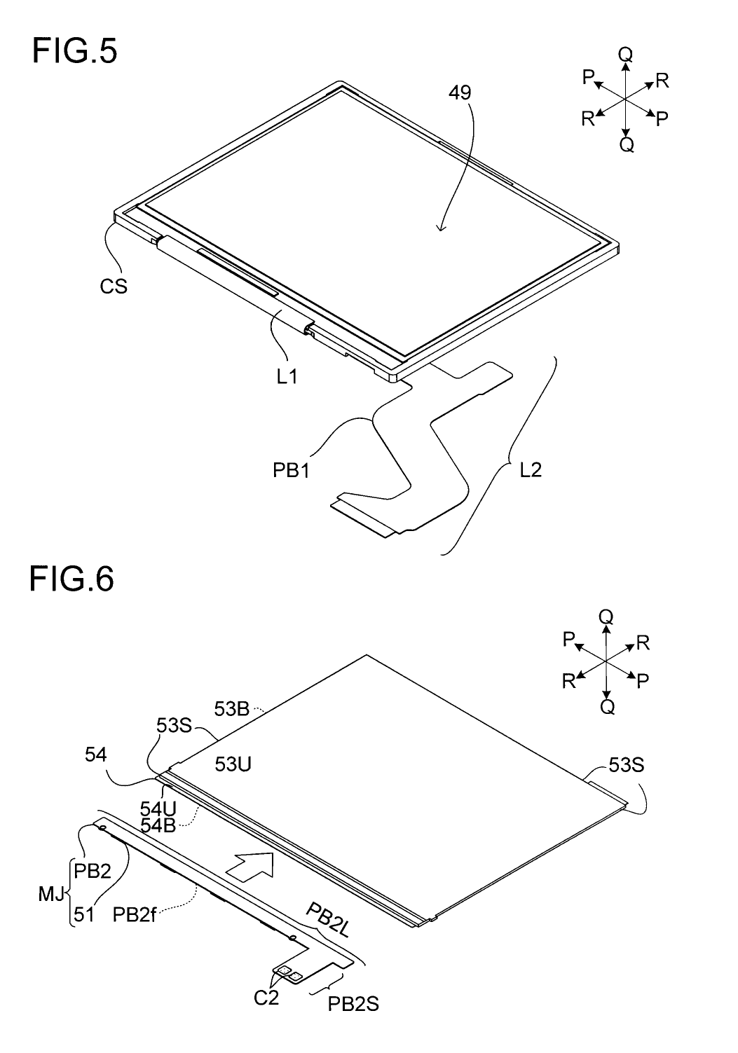

Referring to FIGS. 5 to 15, the description is now directed to how the panel FPC board PB1 and the LED FPC board PB2 are electrically attached to each other, more specifically, fabrication process steps up to electrically connecting the first connection portion C1 of the panel FPC board PB1 to the second connection portion C2 of the LED FPC board PB2 via solder (electrically conductive adhesive) 11.

FIG. 5 shows the liquid crystal display apparatus 69 shown in FIG. 3, with the front bezel BZ1 and the rear bezel BZ2 omitted. The liquid crystal display apparatus 69 in the state shown in FIG. 5 is obtained by following fabrication process steps shown in FIG. 6 and the drawings subsequent thereto. In each of FIGS. 6 to 12, the built-in chassis CS is omitted for the sake of convenience. Furthermore, the fabrication process steps described below are illustrative without any limitation thereto.

First, as shown in FIG. 6, the LED module MJ is brought close to the light guide plate 53 covering the reflection sheet 54. To be more specific, the LED module MJ is brought close to the one of the side surfaces 53S of the light guide 53, which functions as a light receiving surface 53S, so that the light emitting surface of the LED 51 faces the one of the side surfaces 53S of the light guide plate 53 (when the LED module MJ is brought close to the one of the side surfaces 53S of the light guide plate 53, the mounting surface PB2f of the LED FPC board PB2 is oriented to a rear bezel BZ2 side, and a tip end of the shorter portion PB2S of the L-shaped LED FPC board PB2 is at a distance from the light receiving surface 53S of the light guide plate 53).

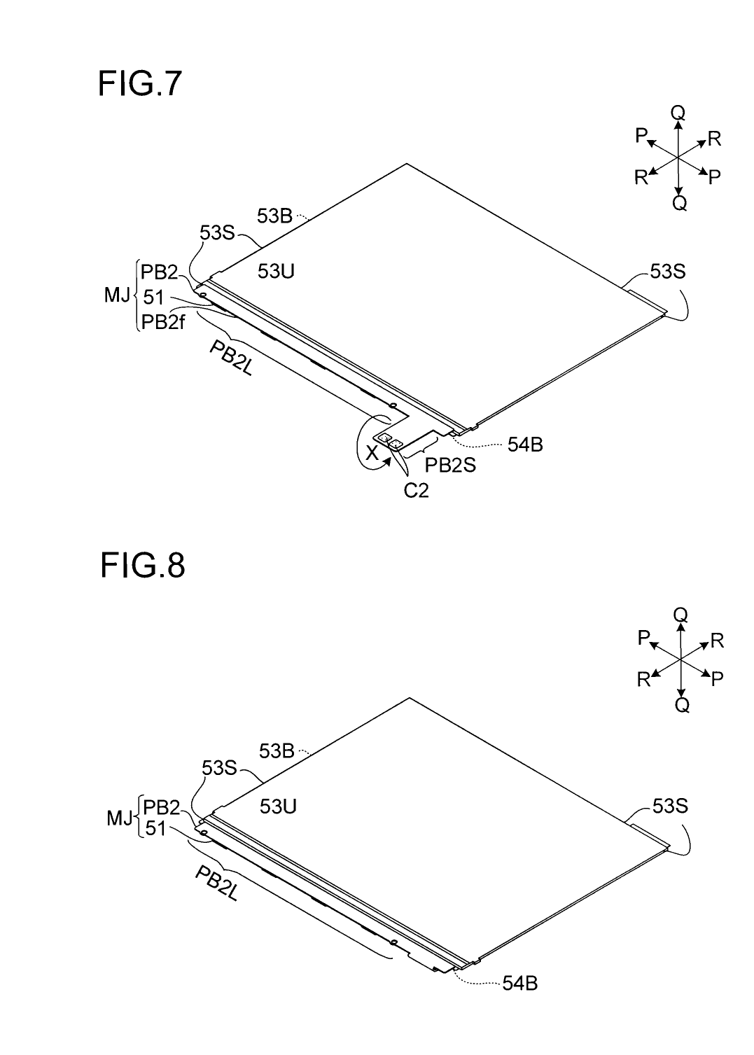

After that, a part of the LED FPC board PB2 of the LED module MJ is bent. To be more specific, as shown in FIG. 7, in the L-shaped LED FPC board PB2, with reference to the vicinity of an intersection between the longer portion PB2L and the shorter portion PB2S, the shorter portion PB2S is bent toward the reflection sheet 54 (more specifically, the non-reflection surface 54B) in a direction indicated by an arrow X. As a result, as shown in FIG. 8, a region of the mounting surface PB2f, which is located in the shorter portion PB2S, faces the non-reflection surface 54B of the reflection sheet 54.

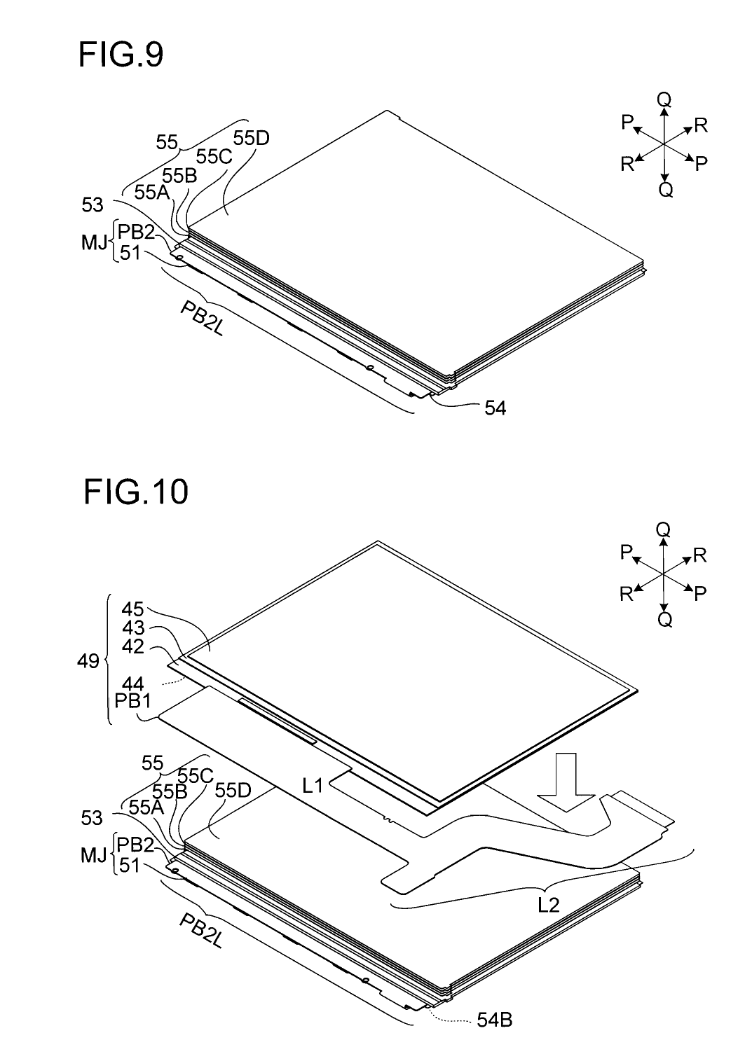

After this, as shown in FIG. 9, the optical sheet group 55 is stacked on the top surface 53U of the light guide plate 53, and, as shown in FIG. 10, the liquid crystal display panel 49 is further placed over the optical sheet group 55. To be more specific, the liquid crystal display panel 49 is brought close to the optical sheet group 55 so that the polarization sheet 44 of the liquid crystal display panel 49 faces the diffusion sheet 55D.

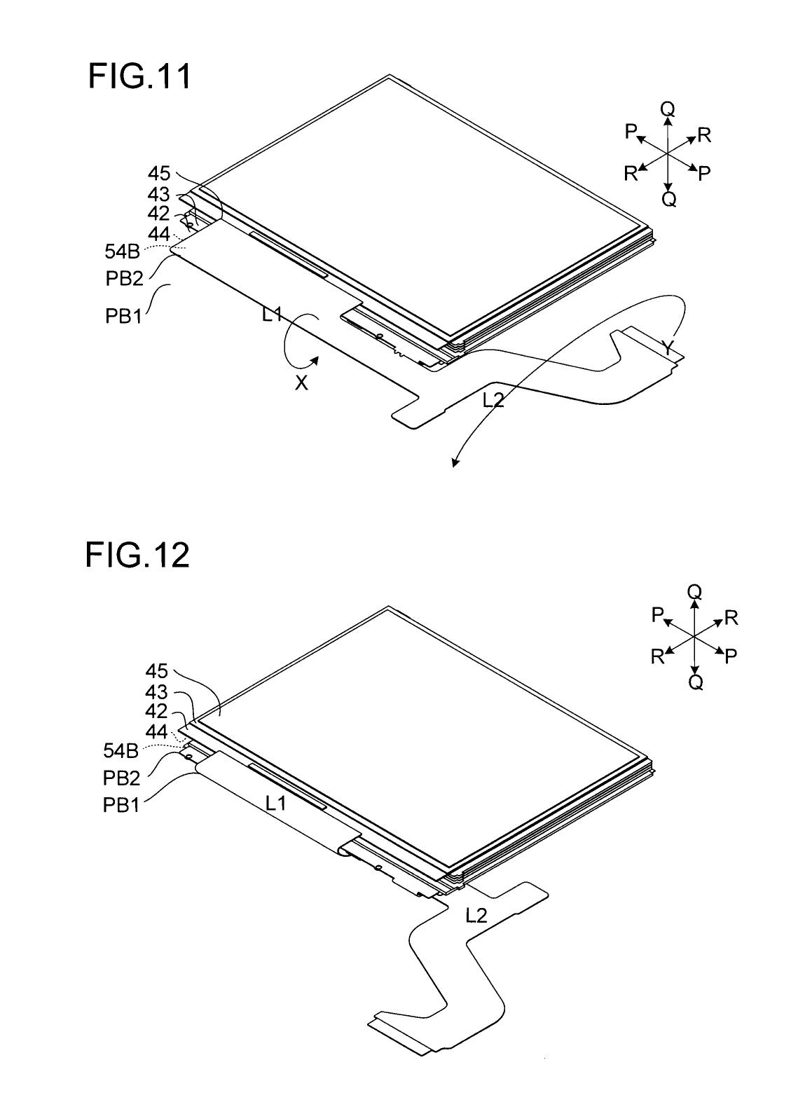

Next, the first extending portion L1 of the panel FPC board PB1 is bent. To be more specific, with reference to the vicinity of a middle in width of the first extending portion L1 in the intersecting direction R, the first extending portion L1 is bent toward the non-reflection surface 54B of the reflection sheet 54 in a direction indicated by an arrow X shown in FIG. 11 (see FIG. 12). Furthermore, when the first extending portion L1 is bent in this manner, the second extending portion L2 is turned over in a direction indicated by an arrow Y shown in FIG. 11 (see FIG. 12).

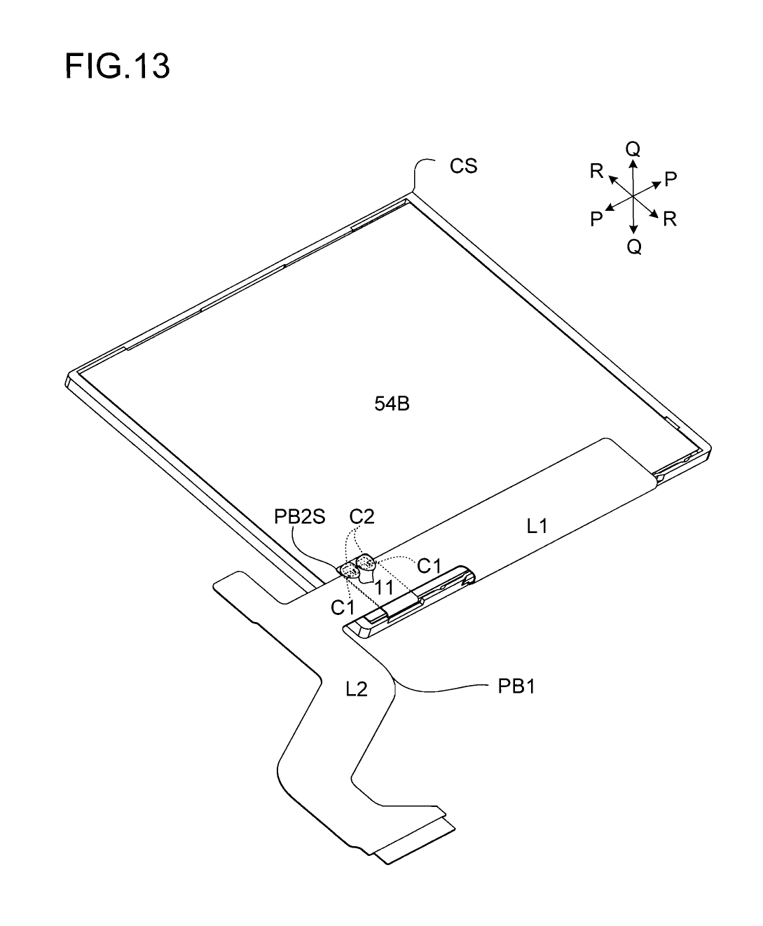

As a result, as shown in FIG. 13 showing the non-reflection surface 54B of the reflection sheet 54 and FIG. 14 that is a partially enlarged view of FIG. 13 (in each of FIGS. 13 and 14, the built-in chassis CS is also shown), the first extending portion L1 is laid over the shorter portion PB2S of the LED FPC board PB2, which is laid over the non-reflection surface 54B. Moreover, the first connection portion C1 in the first extending portion L1 of the panel FPC board PB1 and the second connection portion C2 (see a halftone dotted area) in the shorter portion PB2S of the LED FPC board PB2 are so designed as to be superposed on each other.

For example, as shown in FIG. 14, in a case where the second connection portion C2 is formed in the vicinity of the tip end of the shorter portion PB2S of the LED FPC board PB2, the first connection portion C1 is formed at a part (for example, an edge) of the first extending portion L1 of the panel FPC board PB1, which is superposed on the second connection portion C2. Thus, these connection portions C1•C2 are superposed on each other, and the solder 11 is further applied to both the connection portions C1•C2.

In order, however, that, after the panel FPC board PB1 and the LED FPC board PB2 have been superposed on each other, the first connection portion C1 and the second connection portion C2 are connected to each other by use of the solder 11, the first connection portion C1 and the second connection portion C2 need to be exposed toward the outside (the point is that they need to be able to be connected to each other from the outside). From this standpoint, in a case where, as shown in FIG. 14, the first extending portion L1 of the panel FPC board PB1 is superposed on the shorter portion PB2S of the LED FPC board PB2, the following configuration could be adopted.

That is, the first connection portion C1 is formed by gold-plating a U-shaped notch provided at the edge of the first extending portion L1 superposed on the shorter portion PB2S, and the second connection portion C2 in the form of a pad formed by gold plating is formed in a region of the shorter portion PB2S in the vicinity of an end thereof, one part of which is superposed on the first connection portion C1, and the other part of which is not superposed on the panel FPC board PB1 but is exposed.

With the above-described configuration, the first connection portion C1 is superposed on a part of the second connection portion C2. Consequently, the solder 11 is applied (placed in a heap) so as to cover both the connection portions C1•C2 from above the first extending portion L1 of the panel FPC board PB1, which is superposed on the shorter portion PB2S of the LED FPC board PB2.

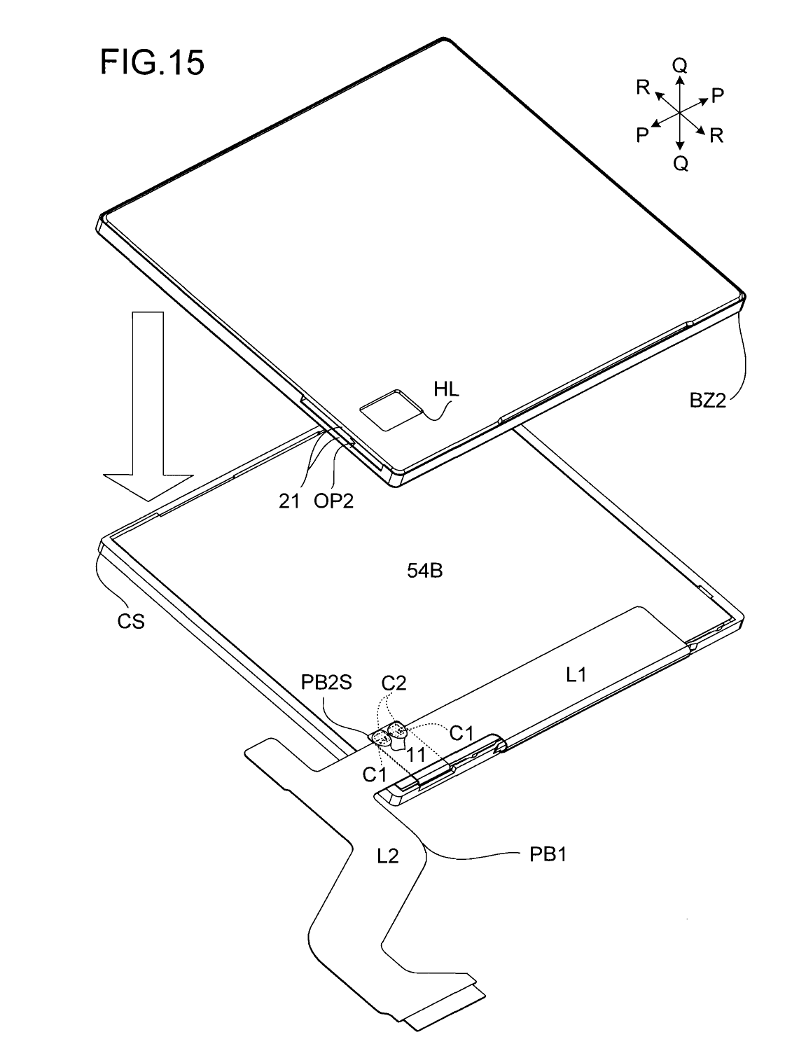

After the LED FPC board PB2 and the panel FPC board PB1 have been electrically connected to each other by use of the solder 11, as shown in FIG. 15, the rear bezel BZ2 is brought close toward the non-reflection surface 54B of the reflection sheet 54 fitted within the frame of the built-in chassis CS and mounted to the built-in chasses CS (there is no particular limitation on how it is mounted). On a side surface of the box-shaped rear bezel BZ2, an opening (drawing-out opening) OP2 is formed, and the second extending portion L2 of the panel FPC board PB1 is drawn out through the opening OP2 to the outside of the rear bezel BZ2.

Furthermore, the front bezel BZ1 is brought close toward the polarization film 45 of the liquid crystal display panel 49 fitted within the frame of the built-in chassis CS and mounted to the built-in chassis CS and to the rear bezel BZ2 (there is no particular limitation on how it is mounted). Furthermore, on a side surface of the frame-shaped front bezel BZ1, a cutout (drawing-out opening) OP1 is formed, and the second extending portion L2 of the panel FPC board PB1 is drawn out through the cutout OP1 to the outside of the front bezel BZ1 (see after-mentioned FIG. 16).

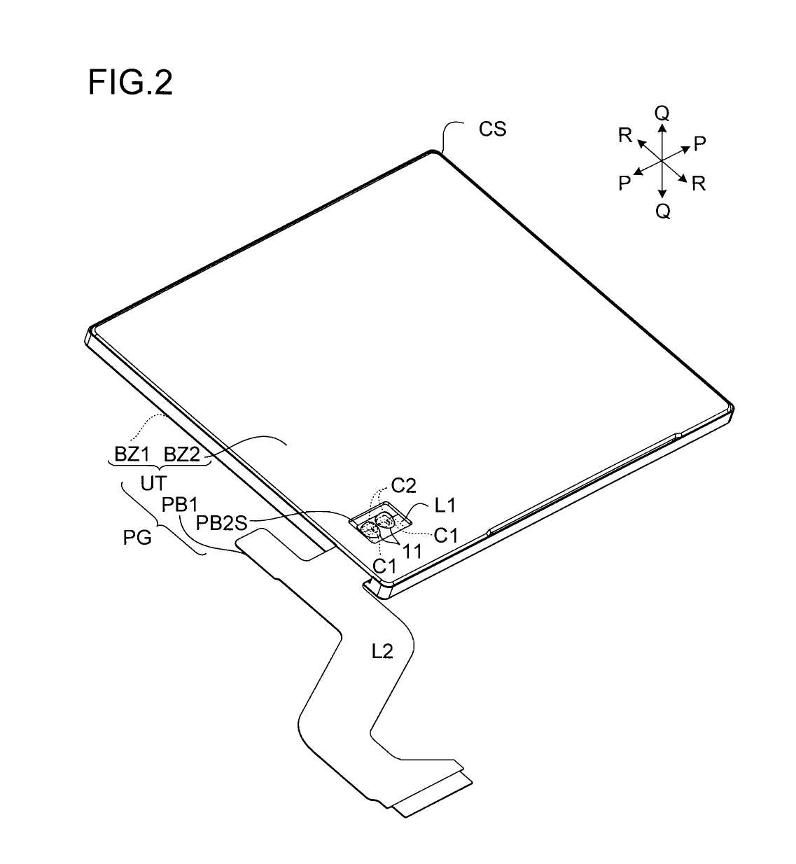

The liquid crystal display apparatus 69 completed in the above-described manner is shown in perspective in FIGS. 3 and 2. As shown in FIG. 2 and FIG. 1 (a partially enlarged view of FIG. 2), the solder 11 is exposed from the inside of the liquid crystal display apparatus 69 (space enclosed between the front bezel BZ1 and the rear bezel BZ2) toward the outside. To be more specific, in the space enclosed between the front bezel BZ1 and the rear bezel BZ2, at a part of the rear bezel BZ2, which is positioned in front of the solder 11, a hole (exposure hole) HL is formed through which the solder 11 is exposed from the inside of the space to the outside thereof.

With the above-described exposure hole HL present, even if the rear bezel BZ2 is made of a metal or the like having conductivity, since the solder 11 heaped above both the boards PB1•PB2 does not come into contact with the rear bezel BZ2, the occurrence of a short circuit (leakage) is prevented. That is, in no case does an electric current flow from the solder 11 to the rear bezel BZ2. Thus, breakage or the like of the liquid crystal display apparatus 69 attributable to leakage is also prevented.

Furthermore, the first extending portion L1 of the panel FPC board PB1 and the shorter portion PB2S of the LED FPC board PB2, to which the solder 11 is applied, are pressed against by the rear bezel BZ2 and thus can hardly be moved (more specifically, the first extending portion L1 and the shorter portion PB2 that are housed inside the rear bezel BZ2 can hardly be moved). Thus, since these respective parts of both the FPC boards PB1•PB2 are prevented from being displaced, the solder 11 is also unlikely to be displaced. Consequently, for example, the solder 11 is prevented from being displaced to come into contact with an edge of the exposure hole HL, and thus breakage or the like of the liquid crystal display apparatus 69 attributable to leakage is further prevented.

Moreover, providing the above-described exposure hole HL eliminates the need for the solder 11 to be covered with a separate insulation member (such as an insulation tape) for the prevention of the occurrence of leakage. Thus, since an insulation member is not required, the cost of the liquid crystal display apparatus 69 is suppressed. Furthermore, covering the solder 11 with an insulation member causes the thickness of the liquid crystal display apparatus 69 to be increased due to the thickness of the insulation member. On the other hand, providing the exposure hole HL does not cause the thickness of the liquid crystal display apparatus 69 to be increased. That is, the liquid crystal display apparatus 69 is made relatively thin (needless to say, a liquid crystal television that includes this liquid crystal display apparatus 69 is also made thin).

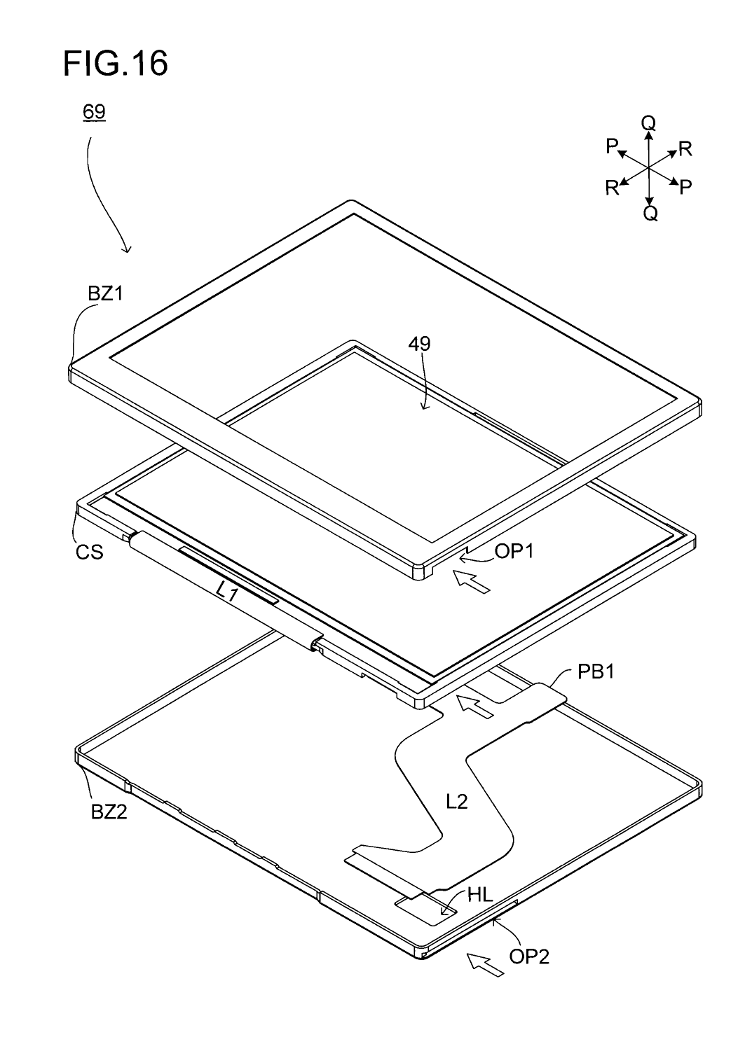

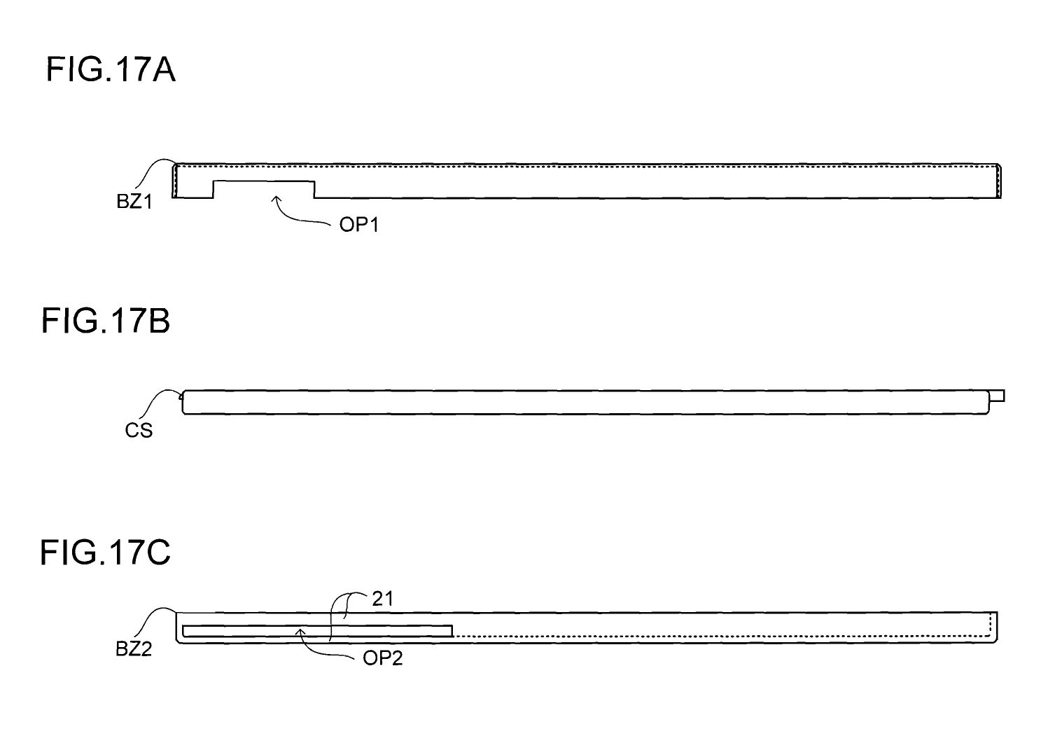

By the way, as shown in the exploded perspective view of the liquid crystal display apparatus 69 in FIG. 16, FIG. 17A that is a side view of the front bezel BZ1, and FIG. 17C that is a side view of the rear bezel BZ2, the panel FPC board PB1 is drawn out to the outside through the cutout OP1 of the front bezel BZ1 and through the opening OP2 of the rear bezel BZ2 (hollow arrows in FIG. 16 indicate a front direction in FIG. 17A to FIG. 17C).

Since, as shown in FIGS. 7•8, the shorter portion PB2S of the LED FPC board PB2 is bent toward inside the frame of the built-in chassis CS (not shown in FIGS. 7•8), as shown in the side view in FIG. 17B, there is no need for the built-in chassis CS to be provided with a drawing-out opening for drawing out the shorter portion PB2S.

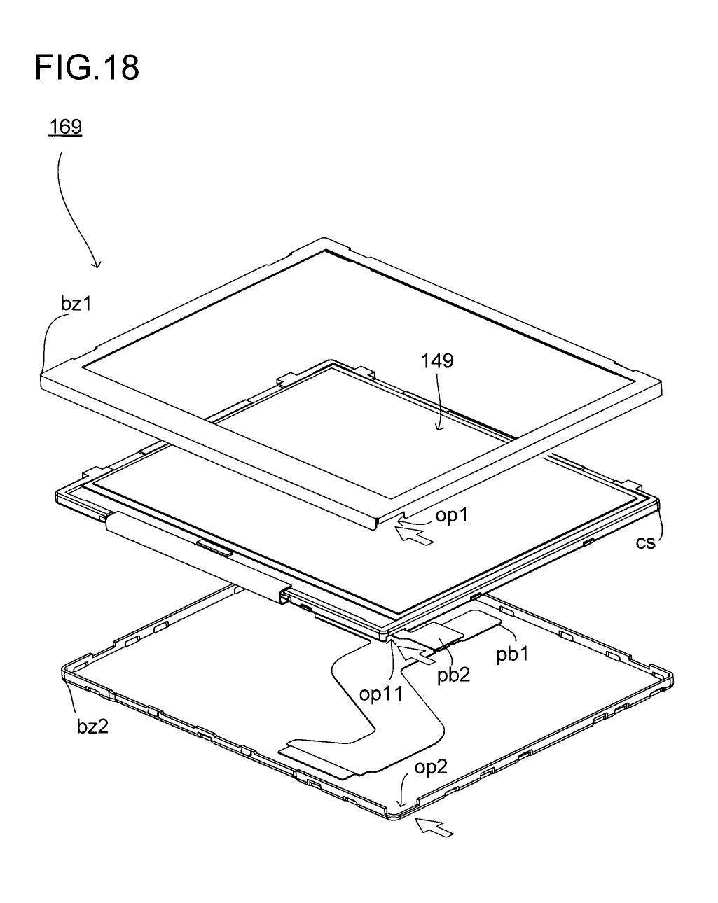

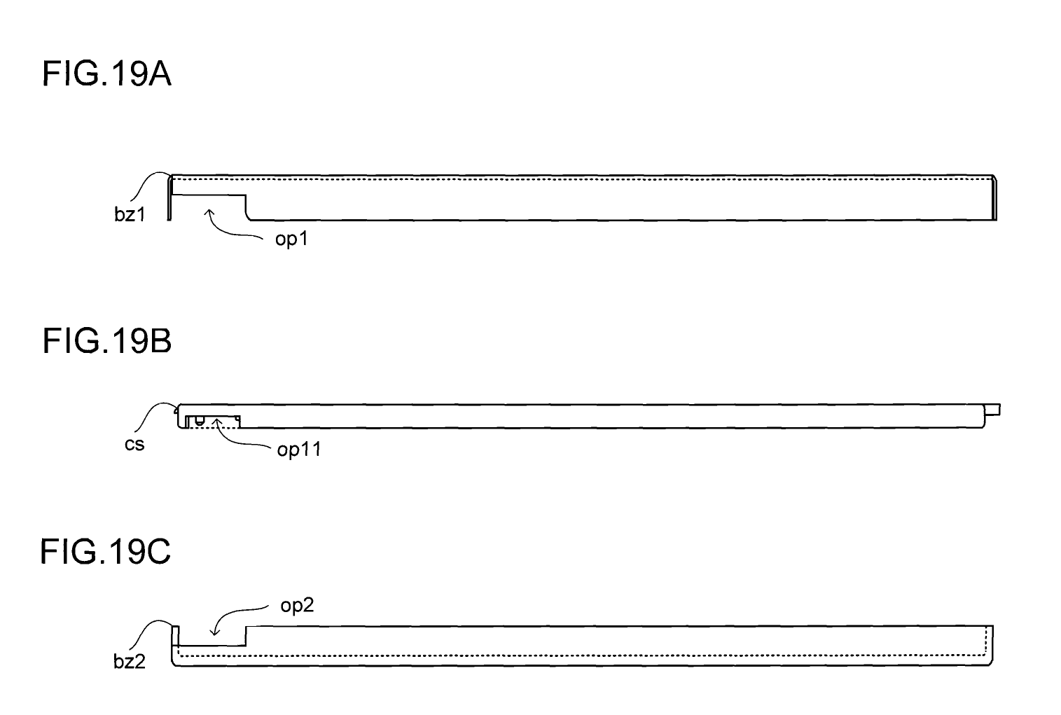

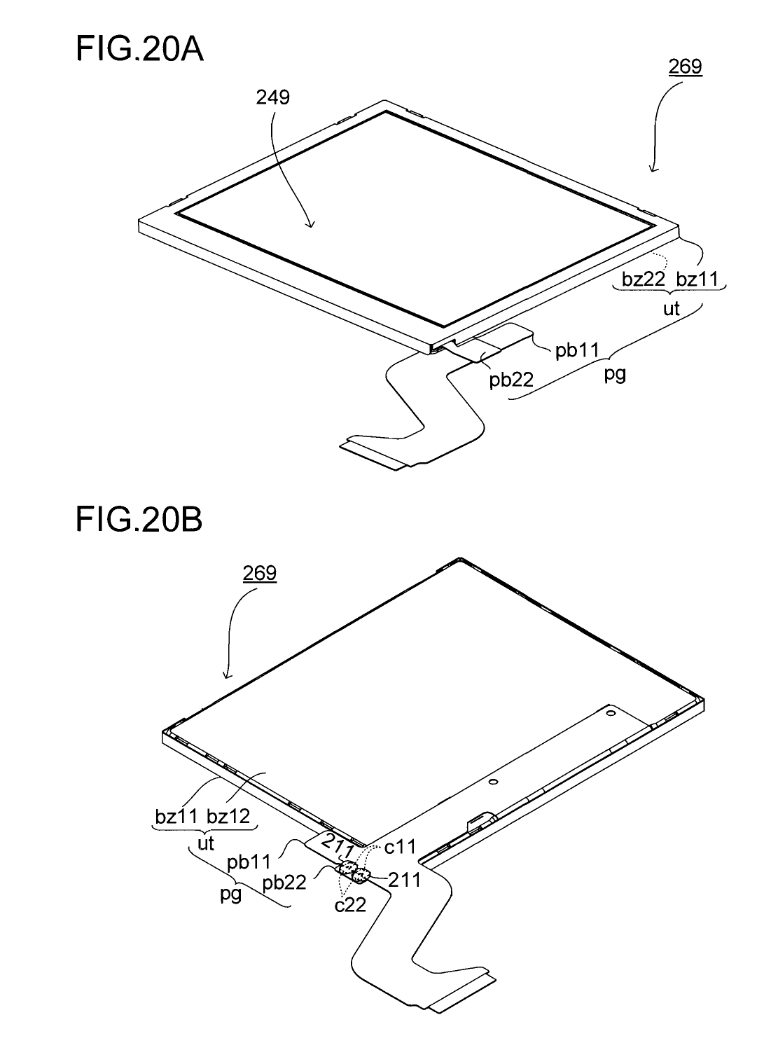

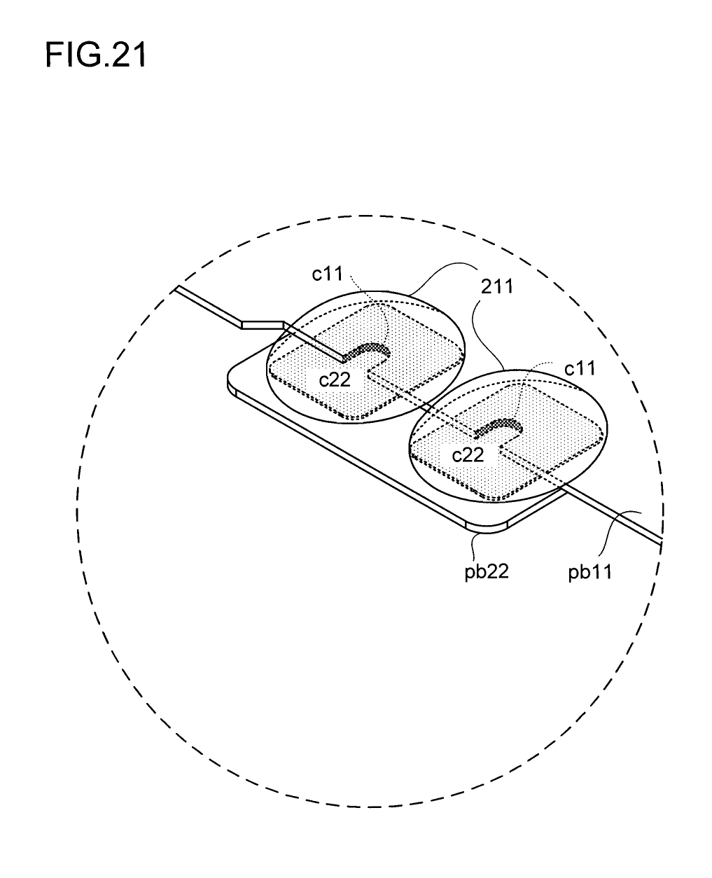

In a case, however, where, as shown in the exploded perspective view in FIG. 18 showing a liquid crystal display apparatus 169 as a comparative example and FIG. 19B that is a side view of a built-in chassis cs, an LED FPC board pb2 is not bent toward inside the frame of the built-in chassis cs, it is required that a drawing-out opening op11 for drawing out the LED FPC board pb2 be formed in the built-in chassis cs. Furthermore, in a case where a panel FPC board pb1 is drawn out from the liquid crystal display apparatus 169, as shown in the side view in FIG. 19A and the side view in FIG. 19C, drawing-out openings are formed in a front bezel bz1 and a rear bezel bz2, respectively (for example, cutouts op1•op2 are formed on side surfaces of these bezels bz1•bz2, respectively).

If, however, as shown in FIG. 18 and FIGS. 19A to 19C (hollow arrows in FIG. 18 indicate a front direction in FIGS. 19A to 19C), an opening (op1•op2•op11) is formed in each of the front bezel bz1, the built-in chassis cs, and the rear bezel bz2 by removing a part thereof, it is likely that a load such as a pressure is applied in a concentrated manner to the vicinity of the opening. It is therefore also likely that a pressure is applied to a region of a liquid crystal display panel 149 in the vicinity of where the openings (op•op2•op11) are collectively aligned, and a crack (tear) might develop in the entire area of the liquid crystal display panel 149, starting from the region to which the pressure is applied.

On the other hand, in a case of the liquid crystal display apparatus 69 shown in FIG. 16, the frame-shaped built-in chassis CS forming a skeleton thereof is housed in the housing unit UT composed of the front bezel BZ1 and the rear bezel BZ2, and the shorter portion PB2S of the LED FPC board PB2, to which the solder 11 is applied, is bent so as to be housed within the frame of the built-in chassis CS. Thus, as shown in FIG. 17B, the built-in chassis CS is not provided with a drawing-out opening. Consequently, the liquid crystal display apparatus 69 housing the built-in chassis CS configured as above as a skeleton thereof has a relatively high strength, and even if a pressure is applied thereto, it is unlikely that the pressure is transmitted to the liquid crystal display panel 49.

Moreover, with the opening OP2 of a loop shape formed in the rear bezel BZ2, as shown in FIG. 17C, a part 21 of the rear bezel BZ2 at a periphery of the opening OP2 functions as a beam. There are provided a plurality of the above-described parts 21, and thus a deterioration in the strength of the rear bezel BZ2 is relatively prevented (for example, the rear bezel BZ2 has a higher strength than the front bezel BZ1 in which the cutout OP1 is formed). Thus, the liquid crystal display apparatus 69 in which the rear bezel BZ2 configured as above is housed together with the built-in chassis CS is further increased in strength, and thus breakage of the liquid crystal display panel 49 is prevented.

### Other Embodiments

The present invention is not limited to the foregoing embodiment and may be variously modified without departing from the scope of the invention.

For example, in the foregoing description, the exposure hole HL for exposing the solder 11 to the outside of the liquid crystal display apparatus 69 is formed in the rear bezel BZ2. There is, however, no limitation thereto. The exposure hole HL may also be formed in, for example, the front bezel BZ1.

Furthermore, in the foregoing description, it is the panel FPC board PB1 that is drawn out through the cutout OP1 of the front bezel BZ1 and through the opening OP2 of the rear bezel BZ2 to the outside. There is, however, no limitation thereto. For example, instead, the LED FPC board PB2 may be drawn out through the cutout OP1 and through the opening OP2 to the outside. Furthermore, both the circuit boards PB1•PB2 may be drawn out through the cutout OP1 and through the opening OP2 to the outside.

### LIST OF REFERENCE SIGNS

11 Electrically conductive solder adhesive (Electrically conductive adhesive)
BZ1 Front bezel (Housing)
OP1 Cutout (Drawing-out opening)
BZ2 Rear bezel (Housing)
HL Exposure hole
OP2 Opening
21 Beam
UT Housing unit
PB1 Panel FPC board (First circuit board)
L1 First extending portion
C1 First connection portion
L2 Second extending portion
PB2 LED FPC board (Second circuit board)
PB2L Longer portion
PB2S Shorter portion
C2 Second connection portion
PG Electronic package
42 Active matrix substrate
49 Liquid crystal display panel
MJ LED module
51 LED
53 Light guide plate
54 Reflection sheet
55 Optical sheet group
CS Built-in chassis (Chassis)
59 Backlight unit
69 Liquid crystal display apparatus (Display apparatus)

1. An electronic package, comprising:
a first circuit board;
a second circuit board; and
a housing unit that houses both the circuit boards,
wherein conduction is established between the first circuit board and the second circuit board via an electrically conductive adhesive, and
an exposure hole through which the electrically conductive adhesive is exposed from an inside of the housing unit to an outside thereof is formed at a part of the housing unit, which is positioned in front of the electrically conductive adhesive.

2. A display apparatus comprising the electronic package according to claim 1,
wherein the first circuit board is a flexible circuit board connected to a display panel,
the second circuit board is a flexible circuit board on which a light emitting element is mounted, and
the electrically conductive adhesive is solder

3. The display apparatus according to claim 2,
wherein a chassis that has a shape of a frame and forms a skeleton of the display apparatus is housed in the housing unit, and
a part of the second circuit board, to which the electrically conductive adhesive is applied, is bent so as to be housed within the frame of the chassis.

4. The display apparatus according to claim 3,
wherein the housing unit is composed of a plurality of housings,
a drawing-out opening through which at least one of the first circuit board and the second circuit board is drawn out to the outside of the housing unit is formed in at least one of the housings, and
the drawing-out opening is a loop-shaped opening.
